(19) United States
(12) Patent Application Publication
(10) Pub. No.: US 2026/0191096 A1
(43) Pub. Date: Jul. 2, 2026

(54) MULTI-CHIP MODULES WITH REDUCED MOLD SHELF

(71) Applicant: Intel Corporation, Santa Clara, CA (US)

(72) Inventor: Telesphor Kamgaing, Chandler, AZ (US)

(73) Assignee: Intel Corporation, Santa Clara, CA (US)

(21) Appl. No.: 19/002,536

(22) Filed: Dec. 26, 2024

(51) Int. Cl. H01L 23/00; H01L 23/31; H01L 25/07

(52) U.S. Cl. CPC H10W 90/00; H10W 72/01351; H10W 72/073; H10W 72/07302; H10W 72/07331; H10W 72/07338; H10W 72/354; H10W 72/387; H10W 74/111; H10W 74/15; H10W 90/724; H10W 90/734

(57) ABSTRACT

An integrated circuit (IC) assembly comprising a multiple IC die coupled to a module routing structure with an underfill material therebetween. A fillet of the underfill material may be confined to be in close proximity with an outer perimeter of the IC die, for example through formation of a barrier material that impedes outflow of the underfill material, or through ablation of an outer perimeter of the fillet. Through confinement of the underfill, dimensions of a multi-chip module may be reduced without exposing any portion of the underfill along a perimeter edge of the module. Following an overmold process, the IC assembly may be singulated into a multi-chip module, which may be further assembled, for example, by attaching the module routing structure to a package substrate structure.

### BACKGROUND

In electronics manufacturing, IC packaging is a stage of semiconductor device fabrication in which an IC that has been monolithically fabricated on a chip, die, or chiplet is assembled into a “package” that can protect each unit from physical damage and communicatively connect it to other co-packaged units. Multiple chiplets can be co-assembled, for example, into a multi-chip module that may then be assembled in a package with a chip-scaled host component, such as a package substrate.

Panel and wafer level assembly of disaggregated chiplets often utilizes both underfill for die attach and over-molding to improve the warpage and handling of the modules. An extended mold shelf may reduce the risk of module delamination or another reliability failure. However, extending the peripheral width of mold material around a module significantly increases the size (e.g., area) of the modules and reduces the number of functional units that can be fabricated per panel or wafer.

Accordingly, module architectures with a reduced mold shelf, and associated methods of manufacture, are commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a flow diagram of methods of forming a multi-chip module with underfill confinement for a reduced mold shelf, in accordance with some embodiments;

FIGS. 2, 3, and 4 illustrate cross-sectional views of a multi-chip module evolving as the methods of FIG. 1 are practiced, in accordance with some embodiments;

FIGS. 5A and 5B illustrate plan views of a multi-chip module with an underfill barrier, in accordance with some embodiments;

FIGS. 6, 7, and 8 illustrate cross-sectional views of a multi-chip module including an underfill barrier evolving as the methods of FIG. 2 are practiced, in accordance with some embodiments;

FIG. 9 illustrates a system employing a multi-chip module including a reduced mold shelf, in accordance with some embodiments;

FIGS. 10 and 11 illustrate cross-sectional views of a multi-chip module evolving as the methods of FIG. 1 are practiced, in accordance with some alternative embodiments;

FIGS. 12A and 12B illustrate plan views of a multi-chip module after underfill trimming, in accordance with some embodiments;

FIGS. 13 and 14 illustrate cross-sectional views of a multi-chip module evolving as the methods of FIG. 2 are practiced following an underfill trim, in accordance with some embodiments;

FIG. 15 illustrates a system employing a multi-chip module with reduced mold shelf, in accordance with some alternative embodiments;

FIG. 16 illustrates a system employing an IC assembly including a multi-chip module with reduced mold shelf, in accordance with some embodiments; and

FIG. 17 is a functional block diagram illustrating an electronic computing device, in accordance with an embodiment of the present invention.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent.

A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

As described further below, an integrated circuit (IC) assembly comprising a multiple IC die structures coupled to a module routing structure has an underfill material therebetween, and a fillet of the underfill material may be confined to be in close proximity with an outer perimeter of the IC die. In some embodiments, the underfill fillet, which may otherwise extend many hundreds of micrometers beyond a perimeter edge of the IC die structures, is confined to less than a couple hundreds of micrometers through the formation of a barrier material that impedes outflow of the underfill material, or through removal of an outer perimeter of the fillet. Fillet trimming may be with laser ablation, for example. Following an overmold process, the IC assembly may be singulated into a multi-chip module, which may be further assembled, for example, by attaching the module routing structure to a package substrate structure. With confinement of the underfill according to embodiments described herein, an extended overmold shelf may be avoided. The reduced mold shelf enables smaller lateral dimensions of a singulated multi-chip module (i.e., module area or footprint) without exposing any portion of the underfill along a perimeter edge of the module that might otherwise lead poor adhesion between the mold material and the underfill material, potentially resulting in delamination and/or moisture penetrating into the multi-die structure module/complex.

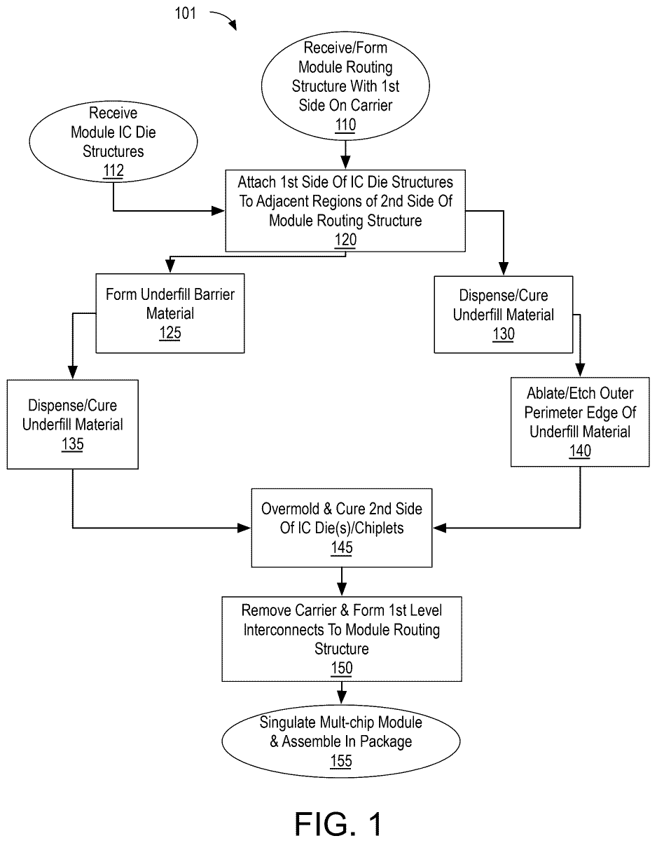

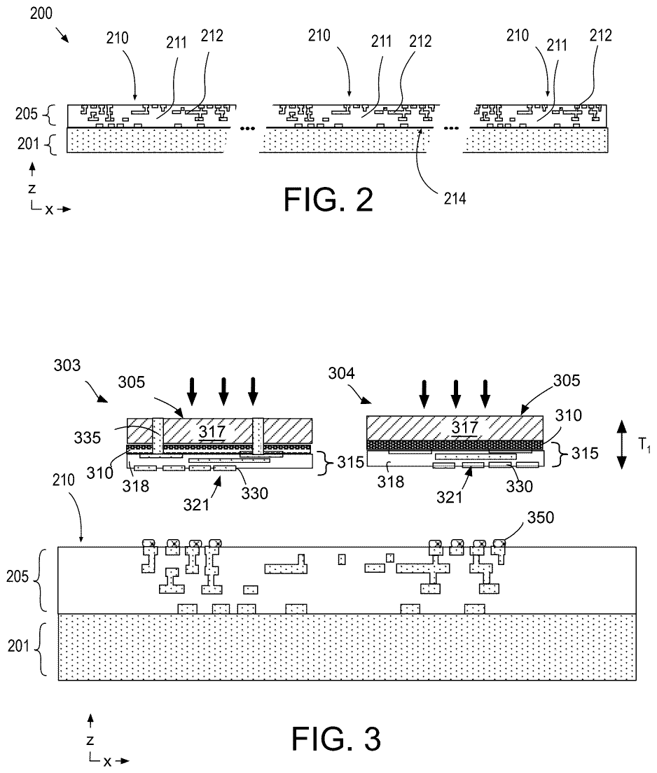

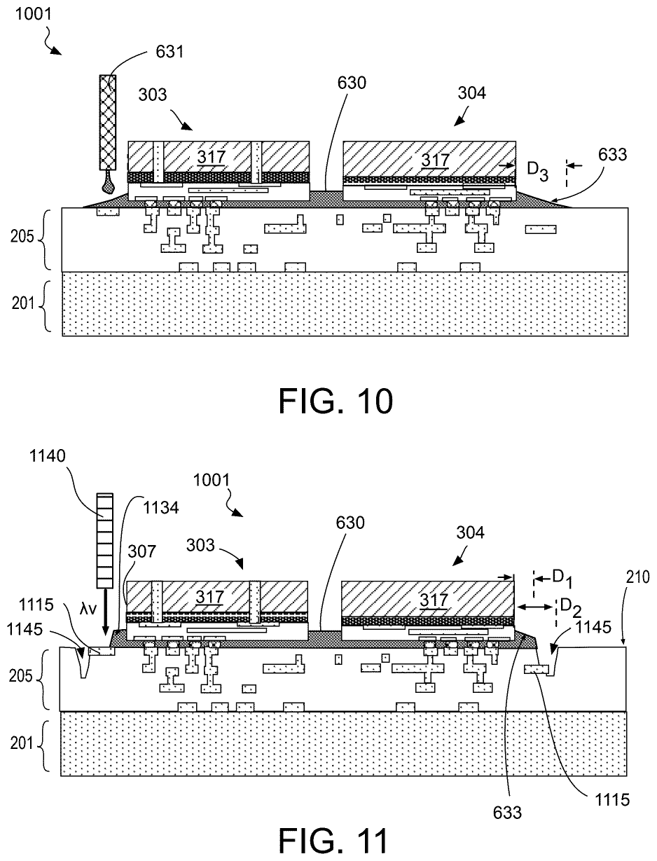

FIG. 1 illustrates a flow diagram of methods 101 for forming an integrated circuit (IC) device assembly including a multi-chip module with underfill confinement for a reduced mold shelf, in accordance with some embodiments. FIG. 2-9 illustrate an exemplary IC assembly evolving as the methods 101 are practiced, in accordance with some embodiments where an underfill fillet is contained by a flow barrier. FIG. 10-15 illustrate an exemplary IC assembly evolving as the methods of FIG. 2 are practiced, in accordance with some alternative embodiments where an underfill fillet is patterned. For clarity of description, methods 101 are described first in conjunction with FIG. 2-9, which provide illustrative examples of some advantageous embodiments. Methods 101 are then further described in conjunction with FIG. 10-15, which provide illustrative examples of some other advantageous embodiments. However, not all embodiments of methods 101 require all the features exemplified in FIG. 2-9 or FIG. 10-15.

As shown in FIG. 1, methods 101 begin at input 110 where a module base is received. In exemplary embodiments, the module base comprises a routing structure that is to become electrically coupled to one or more IC die structures. A workpiece received at input 110 may be a wafer or panel comprising a plurality of modules, for example. In the embodiments further illustrated by the cross-sectional view of FIG. 2, a wafer/panel-level workpiece 200 comprises a plurality of module bases 205 arrayed over a wafer or panel carrier 201. Carrier 201 may be any support known to be suitable for wafer or panel level assembly, such as a glass wafer (e.g., 300 mm diameter, etc.) or large format glass panel. Carrier 201 may therefore be predominantly silica (e.g., silicon and oxygen) and may further include one or more metals, such as, but not limited to aluminum, beryllium, magnesium, calcium, strontium barium, or radium. Additional dopants (e.g., boron, phosphorus) may also be present in carrier 201 (e.g., borosilicate glass, etc.).

Each module base 205 comprises a dielectric material 211 and one or more levels of routing metallization features 212. Dielectric material 211 and routing metallization features 212 may be built up upon a side of carrier 201, for example with semi-additive processing (SAP) techniques. In some embodiments, dielectric material 211 is an organic material, such as, an epoxy resin, phenolic-glass, or a resinous film such as the GX-series films commercially available from Ajinomoto Fine-Techno Co., Inc. (ABF). Dielectric material 211 may comprise epoxy resins (e.g., an acrylate of novolac such as epoxy phenol novolacs (EPN) or epoxy cresol novolacs (ECN)). In some specific examples, dielectric material 211 is a bisphenol-A epoxy resin, for example including epichlorohydrin. In other examples, dielectric material 211 includes bisphenol-F epoxy resin (with epichlorohydrin). In other examples, dielectric material 211 includes aliphatic epoxy resin, which may be monofunctional (e.g., dodecanol glycidyl ether), difunctional (butanediol diglycidyl ether), or have higher functionality (e.g., trimethylolpropane triglycidyl ether). In still other examples, dielectric material 211 includes glycidylamine epoxy resin, such as triglycidyl-p-aminophenol (functionality 3) and N,N,N′,N′-tetraglycidyl-bis-(4-aminophenyl)-methane (functionality 4).

Levels of conductive routing metallization features 212 are embedded within dielectric material 211. In some embodiments, routing metallization features 212 are Cu (or alloy thereof) and may be formed, for example, with through-mask electroplating processes or an alternative additive/semi-additive process. Together, routing metallization features 212 comprise a routing metallization structure terminating at interconnect interface features (e.g., pads or pillars) on module base side 210 and terminating at interconnect interface features (e.g., pads or pillars) on routing metallization structure side 214. The metallization structure may interconnect multiple die through module base 205 as well as redistribute and/or fan out die structure routing to first-level interconnect interfaces on routing metallization structure side 214.

Although not illustrated, module base 205 may further comprise an IC die structure embedded within dielectric material 211. Such an embedded IC die structure may be a passive die structure lacking any transistors within a device layer and including only backend metallization, for example having a much higher routing density that that of metallization features 212. Alternatively, an embedded IC die structure may be an active die including transistors within a device layer. Accordingly, module base 205 may be any of a silicon or semiconductor die, an organic interposer, an organic interposer with embedded chiplets.

Returning to FIG. 1, methods 101 continue at block 120 where a first side of module IC die structures received at input 112 are attached to a first side of the routing metallization structure of the module base that was received at input 110. Block 120 may be performed as a zeroth level of heterogeneous integration of multiple IC die structures into an assembly that may be further integrated into an electronic system through first level interconnects (FLI) subsequently formed. Attachment operations at block 120 may entail any wafer/panel level processes known to be suitable for heterogenous integration. In some examples, at block 120 a pick-and-place machine positions IC die structures laterally adjacent to each other and solder features are reflowed to bond or attach the IC die structures to module bases.

In the example further illustrated in the cross-sectional view of FIG. 3, multiple IC die structures 303 and 304 are attached to module base side 210. Although only two laterally adjacent IC die structures 303, 304 are illustrated, any number of such IC die structures may be similarly attached to module base 205. In the illustrated example, IC die structures 303, 304 are each singular structures, however IC die structures 303, 304 may each also be composite die structures, for example comprising multiple IC die structures bonded together into a composite IC die structure.

As further illustrated in FIG. 3, IC die structures 303, 304 have IC layers 315 on a front side surface 321 and further comprises a die substrate material 317 on a backside surface 305. In some examples, IC die substrate material 317 is silicon. In other examples, die substrate material 317 is an alternative crystalline material, such as, but not limited to, germanium, SiₓGe₁₋ₓ, GeₓSn₁₋ₓ or silicon carbide. IC die structures 303, 304 are affixed to module base 205 “front-side down,” as shown, so that IC layers 315 are proximal to carrier 201. However, in alternative embodiments IC die structures 303, 304 may instead be assembled “front-side up” so that IC layers 315 are instead distal to carrier 201. For such embodiments, conductive through substrate vias (TSVs) TSVs 335 that extend from backside surface 305 through die substrate material 317 may be coupled to metallization features of module base 205.

IC die structures 303, 304 may each have any architecture. In the illustrated embodiments, each of IC die structures 303, 304 is an “active” IC die with one or more types of active devices within a device layer 310. Such active devices may be fabricated into a surface of die substrate material 317, or not (e.g., instead part of a transferred substrate). Device layer 310 may include any semiconductor material such as, but not limited to, predominantly silicon (e.g., substantially pure Si) material, predominantly germanium (e.g., substantially pure Ge) material, or a compound material comprising a Group IV majority constituent (e.g., SiGe alloys, GeSn alloys). In other embodiments, device layer 310 includes a Group III-V material comprising a Group III majority constituent and a Group IV majority constituent (e.g., InGaAs, GaAs, GaSb, InGaSb). Device layer 310 may have a thickness of 50-1000 nm, for example. Device layer 310 need not be a continuous material layer, but rather may include active regions of semiconductor material surrounded by field regions of isolation dielectric.

In some embodiments, the active devices within device layer 310 are field effect transistors (FETs) with a device pitch of 80 nm, or less. The FETs may be of any architecture (e.g., planar, non-planar, single-gate, multi-gate, stacked nanosheet, etc.). In some embodiments, FET terminals have a feature pitch of 5-20 nm. Additionally, or in the alternative, device layer 310 may include active devices other than FETs. For example, device layer 310 may include electronic memory structures, spin valves, or the like.

IC die structures 303, 304 may comprise one or more IC die metallization levels on either side of device layer 310. In exemplary embodiments, IC layers 315 include die metallization features 330 embedded within an insulator 318. While IC die metallization features 330 may have any composition(s) of sufficient electrical conductivity, in exemplary embodiments, IC die metallization features 330 are predominantly copper (Cu). In other examples, metallization features 330 are predominantly other than Cu, such as, but not limited to predominantly Ru, or predominantly W. An uppermost one of metallization features 330 within IC layers 315 may have a feature pitch ranging from 80 nm to several microns, for example.

IC dies structures 303, 304 may have thickness T₁. In some examples die structure thickness T₁ is 100-500 μm. In the illustrated example, IC die 303 further includes one or more through die substrate vias (TSVs) 335. Die TSVs 335 couple with IC layers 315, for example contacting one or more metallization features and/or terminals of active or passive devices. die TSVs 335 may have any architecture and generally include a metallization, such as, but not limited to, Cu.

Each of IC die structures 303, 304 may be a fully functional ASIC, or may be a chiplet or tile that has more limited functionality supplementing one or more other IC dies that are to be part of the same multi-chip device. A chiplet or tile may, for example, be any of a wireless radio circuit, microprocessor core, electronic memory circuit, floating point gate array (FPGA), power management and/or power supply circuit, and/or include a MEMS device. In some examples, one or more of IC die structures 303, 304 include one or more banks of active repeater circuitry to improve multi-chip interconnects (e.g., network-on-chip architectures). In other examples, one or more of IC die structures 303, 304 include clock generator circuitry or temperature sensing circuitry. In other examples, one or more of IC die structures 303 or 304 include logic circuitry that implement mesh network-on-chip architectures. In still other examples, at least one of IC die structures 303, 304 includes microprocessor core circuitry, for example comprising one or more shift registers. Such microprocessor core circuitry may be part of an intelligence processing unit (IPU), graphical process unit (GPU) or central processing unit, for example. In another embodiments at least one of IC die structures 303, 304 is a photonic IC (PIC), for example comprising one or more optical waveguides, optical multiplexer/demultiplexer, lasers and/or photodetectors. In other embodiments, at least one of IC die structures is an application specific IC (ASIC), an electronic memory chip (e.g., DRAM, flash memory, etc.), or an artificial intelligence (AI) accelerator.

As further shown in FIG. 3, IC die structures 303, 304 are attached to module base 205 by zeroth level interconnect (ZLI) features 350. ZLI features 350 may be microbumps, for example, which may include a solder alloy, for example. ZLI features 350 may contact each of interconnect interface features on IC die structures 303, 304 and contact corresponding interface features on module base 205.

Returning to FIG. 1 with IC die structures assembled to a multi-die module base, methods 101 either proceed to block 125 where a barrier suitable for containing or impeding the flow of an underfill material subsequently deposited at block 135 is formed, or methods 101 proceed to block 130 where an underfill material is deposited without a flow containment barrier and the underfill material is subsequently trimmed. For all such embodiments, an outer perimeter of the underfill material is confined to be in close proximity to an outer perimeter of the IC die structures, so that a module may have a reduced mold shelf.

For embodiments where block 125 is practiced, a barrier, for example comprising an elevated or raised structure, is fabricated over a portion of a module base in close proximity of one or more perimeter edges of an IC die structure. Although illustrated in FIG. 1 as being post-IC die assembly, block 125 may alternatively be practiced upstream of IC die assembly. In some examples, a barrier material may be dispensed upon a module base surface so as to be adjacent to one or more perimeter edges of an IC die structure. The barrier material dispensed at block 125 may be selected to have flow properties during the dispense that minimize slump prior to curing the barrier material. For example, the barrier material may have a relatively high thixotropic index and/or viscosity.

The barrier material may protrude a height over the module base so as to present a barrier suitable for impeding flow of a subsequently dispensed underfill material. The frame material may therefore define an underfill “keep-in” zone. The frame material may prevent bleed-out, or other unwanted spatial expansion, of an underfill fillet. With the barrier material in place, any suitable underfill applied can be better confined to a limited area of the module base.

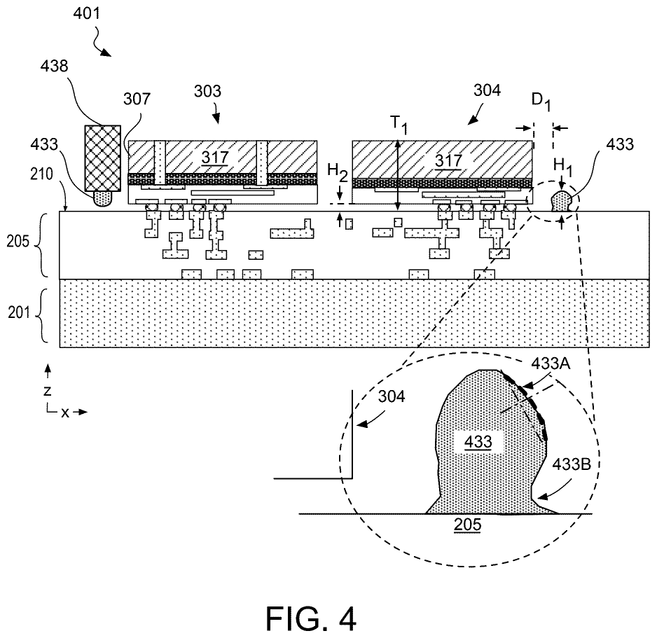

In the example illustrated in FIG. 4, a multi-die module workpiece 401 includes a barrier material 433 that has been dispensed over module base side 210, adjacent to one or more perimeter edges of IC die structures 303, 304. Barrier material 433 may be dispensed by any means suitable to be as close to IC die structures 303, 304 as possible. In some embodiments, a bead of precursor material is extruded and then cured into barrier material 433. In some examples, barrier material 433 is dispensed with an auger or other extruder at high shear rate since barrier material 433 (as-dispensed) advantageously has a high thixotropic index to enable control over the barrier's physical height as well as lateral spread and/or migration of the barrier material relative to edges of IC die structures 303, 304. In other examples, barrier material 433 is printed with an 3D printing technique suitable for the barrier material composition. 3D printing techniques include fused deposition modeling (FDM), for example. The dispense or printing technique(s) employed may advantageously allow for tuning of a barrier material's height and lateral spread, for example through control of a dispense gap and dispense rate (weight and/or speed).

For the exemplary multi-die module workpiece 401 illustrated in FIG. 4, a dispenser 438 applies a bead of frame material 433 adjacent to IC die perimeter edge 307. As shown, a back-side surface of carrier 201 defines a workpiece x-y plane when positioned on a stage or print bed, for example. The stage or print bed may be physically displaceable along any of the workpiece x-y-z axes to follow a preprogrammed print path relative to module base side 210. While traversing print path, one or more beads or layers of barrier material 433 are output by dispenser 438. Although only one layer of barrier material 433 is illustrated, two or more layers of barrier material 433 may be printed in succession to build-up barrier material 433 to a predetermined barrier thickness or height H₁ (e.g., z-dimension). In advantageous embodiments, barrier height H₁ is greater that an IC die bond-line thickness H₂. In some exemplary embodiments, IC die bond-line thickness height H₂ is less than 25 μm, advantageously no more than 15 μm (e.g., 10-15 μm, or less). Accordingly, barrier height H₁ is advantageously at least 10 μm, and may be 15-30 μm, or more, for example. Such a small thickness is one reason direct printing or dispensing of barrier material 433 is advantageous over the application of a material preform, which might need a thickness of many hundreds of microns for the sake of preform integrity.

At the height H₁, barrier material 433 can function as a barrier against, or impediment to, flow of underfill material that will be applied to backfill bond-line thickness H₂. In some embodiments, an inner sidewall of barrier material 433 is spaced apart from IC die structure perimeter edge 307 by a lateral distance (e.g., x-dimension) D₁ that is less than 700 μm, advantageously less than 500 μm, more advantageously less than 250 μm and most advantageously less than 100 μm. In some exemplary embodiments, distance D₁ is in the range of 50-100 μm. Lateral distance D₁ may be a function of both lateral spread of barrier material 433 and positioning of the print/dispense path relative to IC die structure perimeter edge 307. Although barrier material 433 is illustrated as being spaced apart from IC die structure perimeter edge 307, it may also be in contact with perimeter edge 307 to the extent that the presence of barrier material 433 does not hinder subsequent application of underfill material.

Lateral distance D₁ and height H₁ may both be tightly controlled, through dimensions and properties of barrier material 433. Lateral spread of barrier material 433 may be controlled by limiting post-dispense slump, for example by controlling the temperature of module base side 210 (e.g., providing a low-heat environment) and thixotropic properties of barrier material 433. In some exemplary embodiments shown in the expanded view further depicted in FIG. 4, slump may be controlled so that at least some portion of a transverse cross-sectional profile of barrier material 433 has convex surface curvature 433A. Convex surface curvature 433A may arise as a result of non-zero slump. Such convex curvature is indicative of a direct (e.g., bead) dispense of a high-viscosity/high-thixotropic material, and is in contrast to concave curvature typical of a low-viscosity capillary underfill material fillet. Such convex curvature is also in contrast to a material preform profile, which is typically linear as a result of a through-sheet stamping process. Barrier material 433 may also comprise an advancing concave fillet surface 433B associated with material wetting the module base side 210. These profile features, along with the material dimensions and/or proximity to IC die perimeter edge 307 may be retained following subsequent processing (e.g., cures, reflows, externally applied stress).

Although only a single layer, bead, or filament of barrier material 433 is illustrated in FIG. 4, multiple dispense/print passes may also be performed to achieve a predetermined height H₁. Multi-pass dispense embodiments may increase the aspect ratio of barrier material 433. For example, in a two pass dispense, two beads of a transverse cross-sectional profile having convex curvature may result in a “snow-man” profile indicative of the multiple passes.

In exemplary embodiments, an “as-dispensed” viscosity of barrier material 433 is higher than that of a typical capillary underfill (CUF) material to ensure tight control over height H₁ and edge distance D₁. In some exemplary embodiments, the viscosity of barrier material 433 (as-dispensed) is in the range of 10,000-200,000 centipoise. As noted above, a high thixotropic index (e.g., >3) ensures a low-slump profile is maintained throughout dispense and subsequent thermal processing (e.g., cure).

In some embodiments, barrier material 433 is a polymer dielectric material. Barrier material 433 may be a polymer known to be suitable for overmolding IC die structures, for example. Exemplary polymer chemical compositions include polysiloxanes (silicone), polyurethanes, low T_{g} epoxies, polyacrylates, and thermoplastic elastomers. Many other materials (polymers, or otherwise) may also be suitable as barrier material 433. Barrier material 433 may include one or more fillers (e.g., fumed silica, titanium oxide, zinc oxide, alumina, alumina nitride, or one or more other thixo agents) that may be added to the material system (polymer, or otherwise) to yield a material of sufficiently high thixotropic index.

Following dispense, barrier material 433 may be cured. Any cure process known to be suitable for a particular chemical composition may be practiced as embodiments are not limited in this context. A thermal cure (e.g., laser anneal) or UV cure are two examples. Although an anneal may not be necessary depending on the material composition, a cure may facilitate dispense of barrier material 433, and/or stabilize barrier material 433 against further modification during subsequent assembly processes (e.g., solder reflows, etc.). Height H₂ and distance D₁, profile curvature, and surface contact angle may all be achieved by (or maintained through) the cure process. For embodiments where barrier material 433 is 100% solids, dimensional changes may be minimal. However, if a cure process induces dimensional and/or material property changes in barrier material 433, the dispense may be designed to accommodate such dimensional changes.

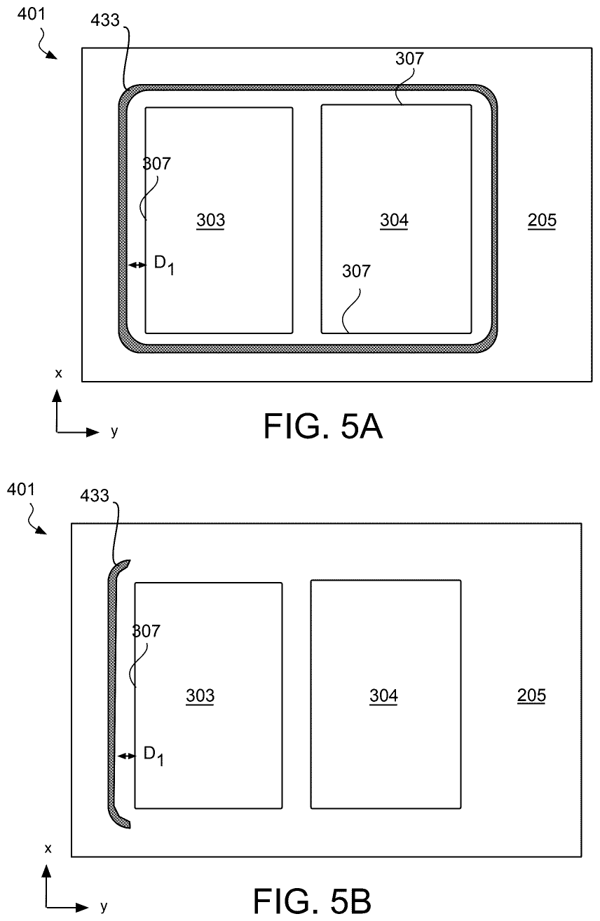

Barrier material 433 may be positioned as needed according to flow characteristics of a subsequently dispense underfill material. In the plan view of FIG. 5A, barrier material 433 forms a frame fully enclosing or encircling perimeter edges 307 of both IC die structures 303 and 304 (or all IC die structures of a multi-chip module). Although barrier material 433 is illustrated as having a relatively constant bead width, barrier material 433 may instead vary in width (and/or height) along its longitudinal length. In other embodiments, segments of barrier material may be separated by gaps introduced, for example, to allow for dispense of underfill material and/or venting/outgassing of underfill material. For example, lengths of barrier material 433 may be bifurcated two or more segments with gap dimensions predetermined to allow for fluid (gas) venting without compromising the ability for barrier material 433 to function as an underfill flow barrier/impediment. In still other embodiments, as illustrated in FIG. 5B, barrier material 433 may only be adjacent to a single perimeter edge 307 of a single IC die structure 303. Hence, barrier material 433 may be formed only where dispense of underfill material would otherwise induce an unacceptably large fillet (e.g., only along a perimeter edge where an underfill dispenser travels).

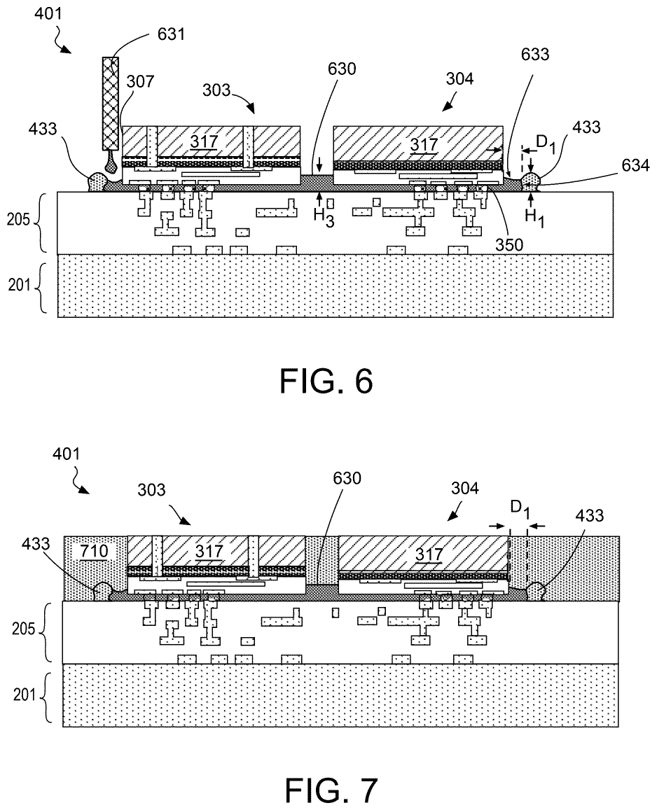

Returning to FIG. 1, methods 101 continue at block 135 where underfill material is dispensed to underfill space between IC die structures and the underlying module base. Following dispense, the underfill material may be cured according to any techniques known to be suitable for the composition of the underfill material. In the example illustrated in FIG. 6, multi-die module 401 includes an underfill material 630, for example that has been dispensed along IC die structure perimeter edge 307 with a needle jet dispenser 631.

Underfill material 630 may have any composition known to be suitable as IC chip underfill. Underfill material 630 may, for example, comprise polyimide or an epoxy resin with a filler, such as fumed silica, or any of the other fillers listed above for barrier material 433. The composition of underfill material 630 is distinct from the chemical composition of barrier material 433, for example to achieve a good coefficient of thermal expansion (CTE) match with ZLI features 350 and/or IC die structures 303, 304. As dispensed, underfill material 630 advantageously has a lower viscosity than barrier material 433 (as dispensed) and generally a sufficiently low viscosity so as to flow under IC die structures 303, 304, for example through capillary action. Underfill material 630 will therefore generally have a fillet with concave curvature typical of low-viscosity capillary transport.

Following dispense, underfill material 630 may be cured (e.g., thermally) to achieve desired thermomechanical properties and/or eliminate void defects in underfill material 630. Following underfill dispense and/or underfill cure, there is an underfill fillet 633 over a portion of module base 205 beyond IC die perimeter edge 307, over some portion of distance D₁. As illustrated, at least some portion of underfill fillet 633 may have a concave surface curvature indicative of a lateral flow beyond IC die perimeter edge 307. As further illustrated, underfill fillet 633 extends to barrier material 433 where underfill material pile-up results in a steep sidewall portion 634 of underfill material 630 being in direct contact with barrier material 433. The cross-sectional profile of underfill material 630 therefore comprises a first, “fillet” portion 633 of lesser slope (that may also be concave) and a second, “steep” or “sheer” portion 634 in contact with barrier material 433. Underfill material may have any center thickness H₃. However, in exemplary embodiments underfill center thickness H₃ is greater than height H₂ (FIG. 4), and may also be greater than barrier height H₁ (FIGS. 1 and 4). As illustrated, barrier height H₁ is advantageously sufficient to fully contain underfill material 630 to within distance D₁.

Returning to FIG. 1, methods 101 continue at block 145 where a dielectric material is deposited over the IC die structures, for example with a wafer/panel-level overmolding process. In exemplary embodiments, the dielectric material is an organic polymer mold material. In the example further illustrated in FIG. 7, a mold material 710 has been molded over IC die structures 303, 304. Mold material 710 has also been molded over barrier material 433 and any exposed underfill material 633, for example within distance D₁. As depicted, mold material 710 has been planarized, for example with a backgrind/polish, that exposes IC die structure substrate material 317. While such a backgrind may be advantageous for thermal management of a multi-die module, mold material 710 may alternatively be retained over IC die structure substrate material 317.

The chemical composition of mold material 710 may vary with implementation. The chemical composition of mold material 710 is advantageously distinct from the chemical composition of underfill material 633. Mold material 710 may, for example, have any of the chemical compositions described above for barrier material 433. In some exemplary embodiments, barrier material 433 and mold material 710 have the same chemical composition. In other embodiments, barrier material 433 and mold material 710 have different chemical compositions. For embodiments, where mold material 710 and barrier material 433 have the same composition, an interface between the bead of barrier material 433 and mold material 710 may nevertheless be visually evident, and substantially as depicted in FIG. 7.

Returning to FIG. 1, methods 101 continue at block 150 where the wafer/panel level carrier is removed from the module base comprising the routing structure. The exposed side of the module base may then be further processed, for example to form first level interconnect features upon interconnect interface features on the second side of the routing metallization structure. Methods 101 then conclude at output 155 with singulation of the wafer or panel into a plurality of multi-chip modules. Singulation is advantageously performed in a manner that limits lateral dimensions of the mold shelf beyond perimeter edges of the IC die structures so as to take advantage of the underfill material containment and/or confinement. In exemplary embodiments, singulation exposes no underfill material, instead only exposing a sidewall of the module base, the overmold material, and potentially some portion of barrier material.

Singulated multi-chip modules may then be further assembled at a next level of system integration, for example with the module's FLI features being attached to a package substrate or other suitable host component. Alternatively, methods 101 may be substantially complete following singulation. A multi-die module may be commercially sold at that point, for example to further assembled by a customer as a component in a computing device. Such a customer may, for example, perform further assembly of the module into a package, etc.

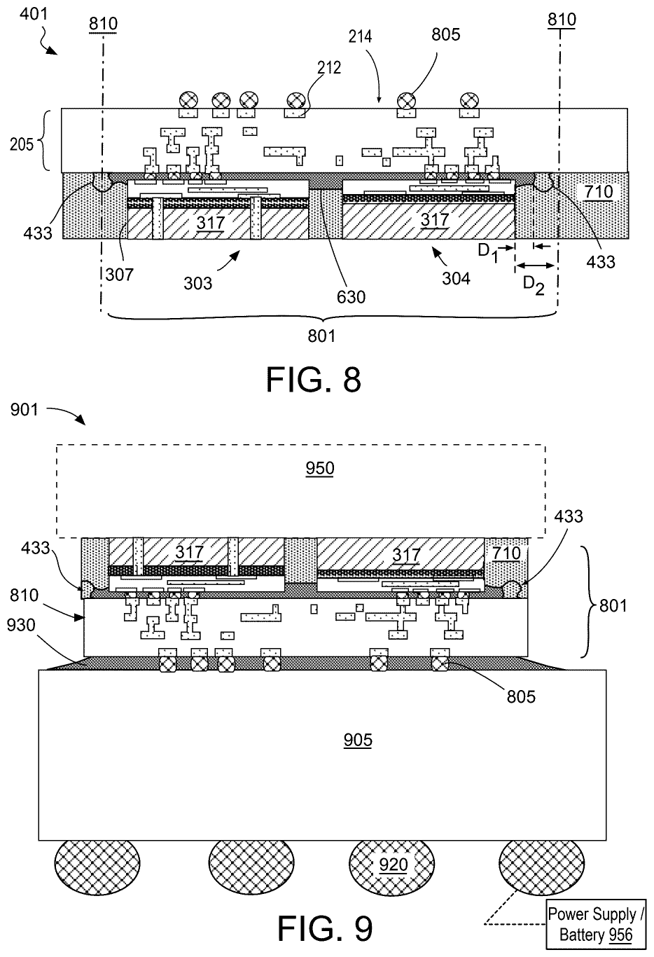

FIG. 8 illustrates an example where multi-die module workpiece 401 has been separated from the carrier to expose metallization features 212 on module base side 214. First level interconnect features 805, for example comprising any suitable solder alloy, is formed on interconnect interface features of exposed on (surface) side 214. Following the formation of FLI features 805, multi-die module workpiece 401 may be singulated along kerf lines 810 to form an individual multi-die module 801. Singulation may be performed with any saw or laser ablation process, for example, as embodiments are not limited in this respect.

As illustrated in FIG. 8, module base 205 is segmented along kerf line 810, which defines a perimeter edge of multi-die module 801. Kerf line 810 also passes through mold material 710. As further illustrated, kerf line 810 may, but need not, also pass through barrier material 433. However, kerf line 810 is controlled to be a distance D₂ from a nearest IC die structure perimeter edge 307, which is outside of distance D₁, and therefore never intersects underfill material 630. Although distance D₂ may vary, in exemplary embodiments, distance D₂ is less than 200 μm (e.g., 100-150 μm). Accordingly, in advantageous embodiments no underfill material 630 is exposed at any perimeter edge of multi-die module 801, including any portion that is most proximal, or nearest, to an IC die structure perimeter edge 307.

FIG. 9 illustrates an exemplary IC device assembly 901, which includes multi-die module 801 attached by FLI features 805 to a package substrate 905. Package substrate 905 may comprise one or more materials known to be suitable as an interposer or package substrate (e.g., an epoxy preform, a glass-cored or coreless copper-clad laminate board, etc.). Package substrate 905 may include one or more metallized redistribution levels (not depicted) embedded within a dielectric material. Package substrate 905 may also include one or more IC die structures embedded therein (not depicted).

Package substrate 905 may further include second level interconnect (SLI) features 920. SLI features 920 may comprise any solder (ball, bump, etc.) suitable for a given host board architecture (e.g., surface mount FR4, etc.) and may be embedded within an underfill material 930. One or more of SLI featurs 920 may provide power from a system-level power supply and/or battery 956. As further illustrated in dashed line, one or more heat spreaders and/or heat sinks or alternative thermal solutions 950 may be further coupled to multi-chip module 801, which may be advantageous, for example, where IC die structures 303, 304 comprise one or more CPU cores or other circuitry of similar power density. Thermal solution 950 may be any heat exchanger, such as a heat sink, cold plate, or heat pipe, etc. that is suitable for dissipating heat generated by an IC die structure.

In accordance with some alternative embodiments, methods 101 (FIG. 1) instead proceed from block 120 to block 130 where underfill material is dispensed without previously forming a flow barrier or impediment. The underfill material fillet 633 is therefore free to spread over a module base surface, potentially many hundreds of micrometers beyond a perimeter edge of an IC die structure. FIG. 10 illustrates a multi-die module workpiece 1001 following a dispense of underfill material 630 upon a multi-die module workpiece comprising IC die structures 303, 304 attached to module base 205 substantially as illustrated in FIG. 3. All structures and features labeled with reference numbers previously described may have any of the attributes previously described. Hence, multi-die module workpiece 1001 may be substantially same as multi-die module workpiece 401 as illustrated in FIG. 6 except barrier material 433 is absent. Accordingly, underfill material 630 may flow unimpeded to distance D₃ beyond a nearest IC die structure perimeter edge 307. Although distance D₃ may vary with implementation, in some embodiments distance D₃ is greater than 500 μm and may be 700 μm, or more.

Returning to FIG. 1, methods 101 continue at block 140 where an outer perimeter edge of the underfill material is ablated, etched, milled, or otherwise removed, such that underfill material does not extend beyond a nearest IC die structure edge by more than a predetermined distance. In the example illustrated in FIG. 11, a laser 1140 emitting energy (λv ) follows a predetermined path that is spaced apart from a nearest IC die structure perimeter edge 307 by distance D₁. Laser 1140 ablates underfill material 630, forming a steep or sheer underfill sidewall portion 1134 that has a steeper slope than fillet portion 633. As further illustrated in FIG. 11, the metallization structure of module base 205 may include one or more metallization features 1115 near distance D₁ that are operable as a stop for laser 1140.

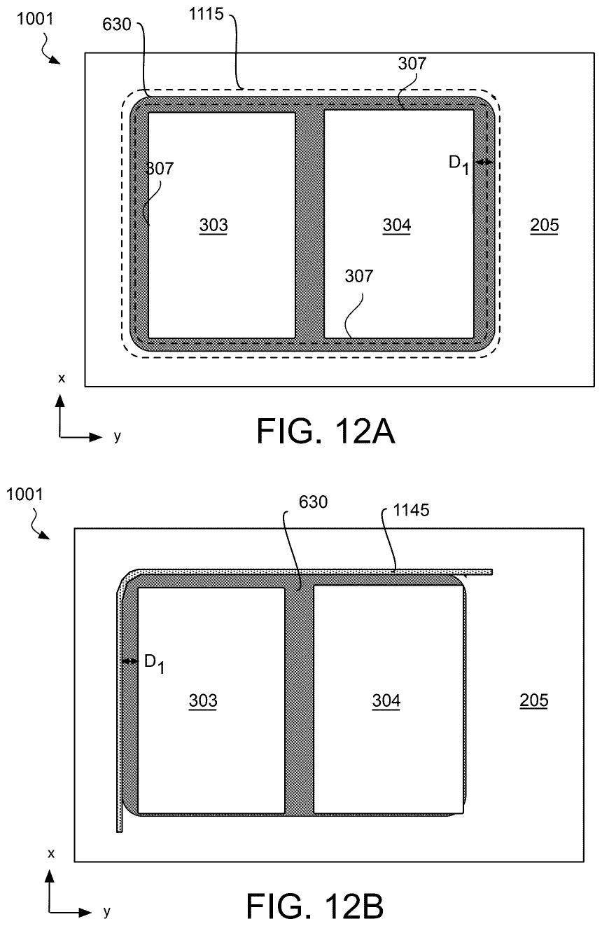

Depending on whether laser stop features 1115 are on module base side 210 or at some underlying metallization level, laser ablation may recess a portion module base side 210, forming one or more trenches 1145 of one or more depths into module base 205 with the deepest portion of such trenches formed where a laser ablation extends beyond an edge of laser stop features 1115. In some embodiments where laser stop features 1115 extend out from a nearest IC die structure perimeter edge 307 by less than distance D₂, a trench 1145 may be located beyond the outer perimeter of laser stop features 1115, for example as illustrated in FIG. 11. FIG. 12A illustrates a plan view of multi-die module workpiece 1001 according to some embodiments where a single, continuous laser stop feature 1115 fully encircles perimeter edges of IC die structures 303, 304. Fully framing the IC die structures, laser stop feature 1115 may accommodate an ablation path to trim a perimeter of underfill material 630 so as to not extend more than distance D₁ beyond any nearest IC die structure perimeter edge 307. FIG. 12B illustrates a plan view of multi-die module workpiece 1001 according to some embodiments where laser stop feature 1115 does not fully encircle all perimeter edges of IC die structures 303, 304. Such partial framing the IC die structures with laser stop feature 1115 may be suitable where an ablation path need only trim underfill material 630 along one or two predetermined IC die structure perimeter edges 307 to ensure underfill material 630 is confined to within distance D₁ around an entire perimeter of all IC die structures.

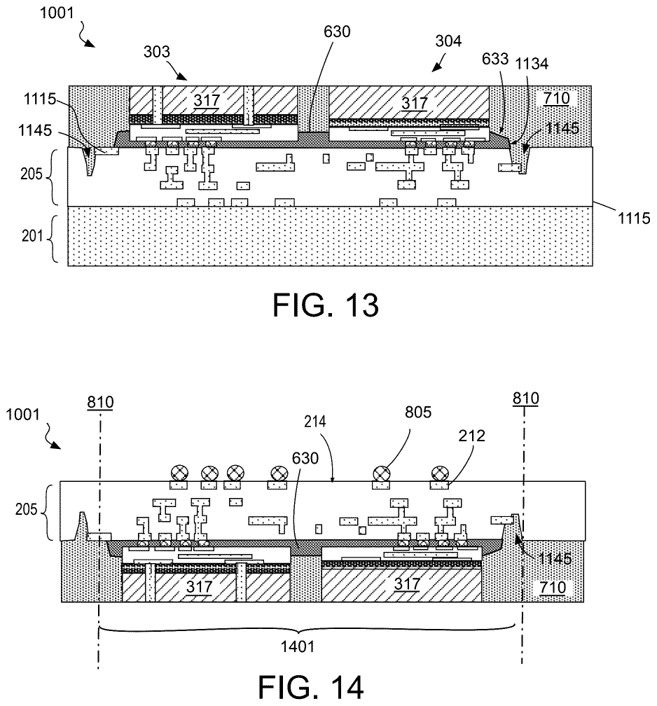

Returning to FIG. 1, methods 101 continue at block 145 where the assembly is overmolded, for example substantially as previously described elsewhere herein. In the example illustrated in FIG. 13, multi-die module workpiece 1001 further includes mold material 710, which has been molded over, and adjacent to, IC die structures 303, 304, and over module base 205 substantially as previously described elsewhere herein. As further illustrated, mold material 710 backfills any trenches 1145 associated with patterning underfill material 630. Mold material 710 is in direct contact both with steep/sheer underfill sidewall portion 1134 and underfill fillet portion 633. As also shown in FIG. 13, mold material 710 has been planarized, for example with a backgrind/polish, that exposes IC die structure substrate material 317. While such a backgrind may be advantageous for thermal management of a multi-die module, mold material 710 may alternatively be retained over IC die structure substrate material 317.

Returning to FIG. 1, methods 101 continue at block 150 where the wafer/panel level carrier is removed from the module base comprising the routing structure, for example substantially as previously described elsewhere herein. The exposed side of the module base may then be further processed, for example to form first level interconnect features upon interconnect interface features on the second side of the routing metallization structure. Methods 101 then conclude at output 155 with singulation of the wafer or panel into a plurality of multi-chip modules. Singulation is advantageously performed in a manner that limits lateral dimensions of the mold shelf beyond perimeter edges of the IC die structures so as to take advantage of the underfill material containment and/or confinement. In exemplary embodiments, singulation similarly exposes no underfill material, instead exposing only overmold material and a sidewall of the module base.

Singulated multi-chip modules may then again be further assembled at a next level of system integration, for example with the module's FLI features being attached to a package substrate or other suitable host component. Alternatively, methods 101 may be substantially complete following singulation. A multi-die module may be commercially sold at that point, for example to be further assembled in a computing device. Such a customer may, for example, perform further assembly of the module into a package, etc.

FIG. 14 illustrates an example where multi-die module workpiece 1001 has been separated from the carrier to expose metallization features 212 on module base side 214. First level interconnect features 805 (e.g., SAC solder alloy) may be formed on interconnect interface features of exposed on side 214. Following the formation of FLI features 805, multi-die module workpiece 1001 may be singulated along kerf lines 810 to form a plurality of multi-die modules 1401. Singulation may be performed with any saw or laser ablation process, for example, as embodiments are not limited in this respect.

As illustrated in FIG. 14, module base 205 is segmented along kerf line 810, which defines a perimeter edge of multi-die module 801. Kerf line 810 also passes through mold material 710. Kerf line 810 is controlled to be the distance D₂ from a nearest IC die structure perimeter edge 307, which is outside of distance D₁, and therefore never intersects underfill material 630. Although distance D₂ may again vary with implementation, in some examples distance D₂ is less than 200 μm (e.g., 100-150 μm). Accordingly, in advantageous embodiments no underfill material 630 is exposed at any perimeter edge of multi-die module 1401, including any portion that is most proximal, or nearest, to an IC die structure perimeter edge 307.

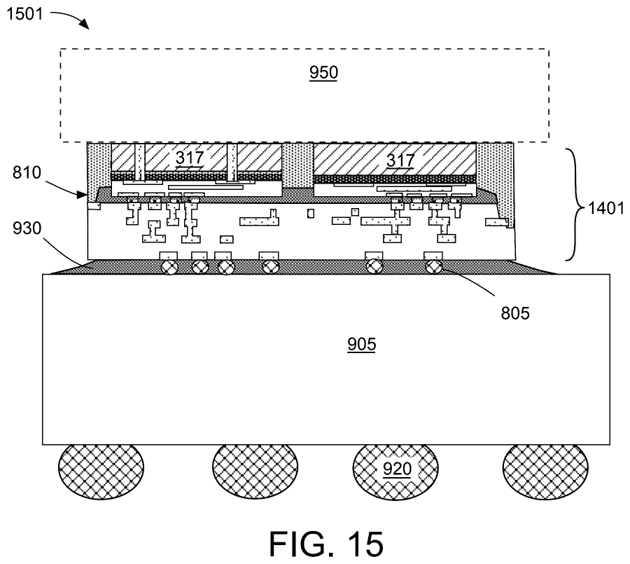

FIG. 15 illustrates an exemplary IC device assembly 1501, which includes multi-die module 1401 attached by FLI features 805 to a package substrate 905. As noted elsewhere herein, package substrate 905 may comprise one or more materials known to be suitable as an interposer or package substrate (e.g., an epoxy preform, a glass-cored or coreless copper-clad laminate board, etc.). Package substrate 905 may include one or more metallized redistribution levels (not depicted) embedded within a dielectric material. Package substrate 905 may also include one or more IC die structures embedded therein (not depicted).

Package substrate 905 may further include second level interconnects (SLI) 920. SLI features 920 may comprise any solder (ball, bump, etc.) suitable for a given host board architecture (e.g., surface mount FR4, etc.). As further illustrated in dashed line, one or more heat spreaders and/or heat sinks or alternative thermal solutions 950 may be further coupled to multi-chip module 1401, which may be advantageous, for example, where IC die structures 303, 304 comprise one or more CPU cores or other circuitry of similar power density. Thermal solution 950 may be any heat exchanger, such as a heat sink, cold plate, or heat pipe, etc. that is suitable for dissipating heat generated by an IC die structure.

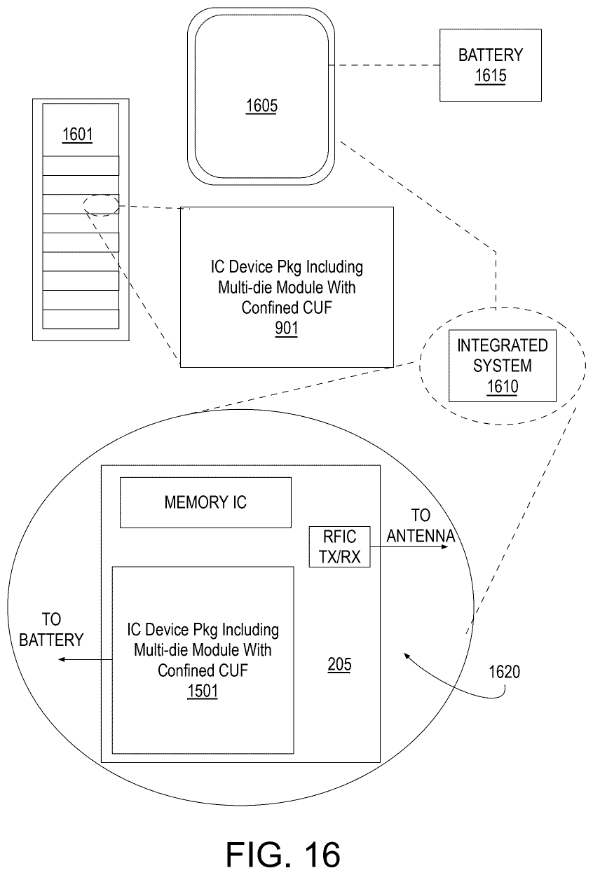

FIG. 16 illustrates some exemplary systems employing an IC assembly including a multi-die module with a spatially contained (capillary) underfill (CUF) material, for example in accordance with any of the embodiments described above. The system may be a mobile computing platform 1605 and/or a data server machine 1601, for example. Either may employ a component assembly including at least one multi-die module with a spatially contained CUF material, for example as described elsewhere herein. The server machine 1601 may be any commercial server, for example including any number of high-performance computing platforms disposed within a rack and networked together for electronic data processing, which in the exemplary embodiment includes IC device assembly 901, for example as described elsewhere herein. The mobile computing platform 1605 may be any portable device configured for each of electronic data display, electronic data processing, wireless electronic data transmission, or the like. For example, the mobile computing platform 1605 may be any of a tablet, a smart phone, laptop computer, etc., and may include a display screen (e.g., a capacitive, inductive, resistive, or optical touchscreen), a chip-level integrated system 1610 further comprising IC device 1501, for example as described elsewhere herein, and a battery 1615.

As illustrated in the expanded view 1620, integrated system 1610 may include one or more of a power management integrated circuit (PMIC) or RF (wireless) integrated circuit (RFIC) including a wideband RF (wireless) transmitter and/or receiver may be further coupled to IC die module base 205. A PMIC may perform battery power regulation, DC-to-DC conversion, etc., and so has an input coupled to battery 1615 and an output providing a current supply to other functional modules. An RFIC may have an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G and beyond.

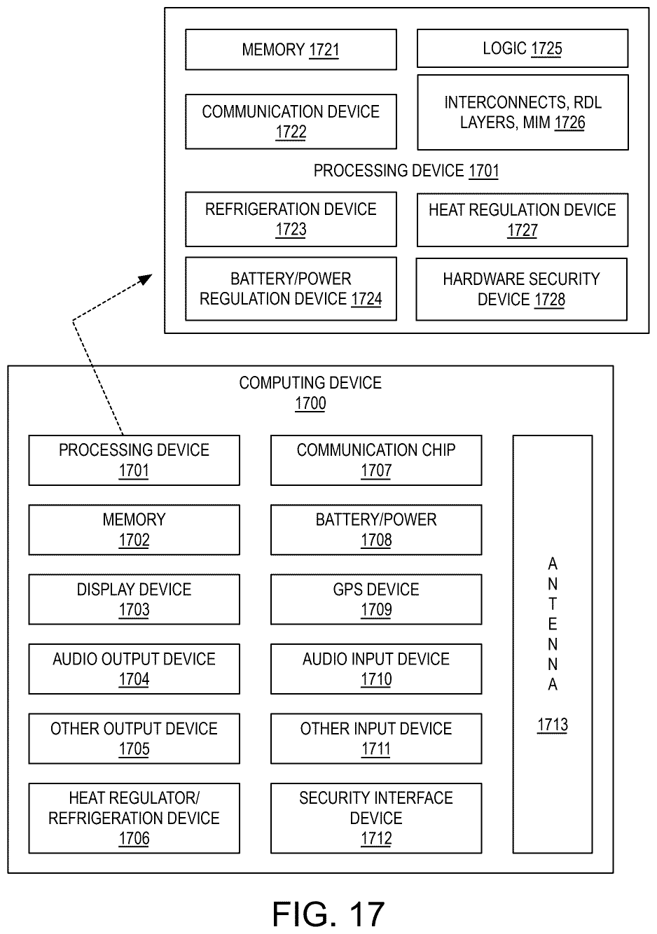

FIG. 17 is a block diagram of a cryogenically cooled computing device 1700 in accordance with some embodiments. For example, one or more components of computing device 1700 may include any of the IC devices or structures discussed elsewhere herein. A number of components are illustrated in FIG. 17 as included in computing device 1700, but any one or more of these components may be omitted or duplicated, as suitable for the application. In some embodiments, some or all of the components included in computing device 1700 may be attached to one or more printed circuit boards (e.g., a motherboard). In some embodiments, various ones of these components may be fabricated onto a single system-on-a-chip (SoC) die. Additionally, in various embodiments, computing device 1700 may not include one or more of the components illustrated in FIG. 17, but computing device 1700 may include interface circuitry for coupling to the one or more components. For example, computing device 1700 may not include a display device 1703, but may include display device interface circuitry (e.g., a connector and driver circuitry) to which display device 1703 may be coupled.

Computing device 1700 may include a processing device 1701 (e.g., one or more processing devices). As used herein, the term processing device or processor indicates a device that processes electronic data from registers and/or memory to transform that electronic data into other electronic data that may be stored in registers and/or memory. Processing device 1701 may include a memory 1721, a communication device 1722, a refrigeration/active cooling device 1723, a battery/power regulation device 1724, logic 1725, interconnects 1726, a heat regulation device 1727, and a hardware security device 1728.

Processing device 1701 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1701 may include a memory 1702, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1721 includes memory that shares a die with processing device 1701. This memory may be used as cache memory and may include embedded dynamic random-access memory (eDRAM) or spin transfer torque magnetic random-access memory (STT-M RAM).

Computing device 1700 may include a heat regulation/refrigeration device 1706. Heat regulation/refrigeration device 1706 may maintain processing device 1701 (and/or other components of computing device 1700) at a predetermined low temperature during operation. This predetermined low temperature may be any temperature discussed elsewhere herein.

In some embodiments, computing device 1700 may include a communication chip 1707 (e.g., one or more communication chips). For example, the communication chip 1707 may be configured for managing wireless communications for the transfer of data to and from computing device 1700. The term “wireless” and its derivatives may be used to describe circuits, devices, systems, methods, techniques, communications channels, etc., that may communicate data through the use of modulated electromagnetic radiation through a nonsolid medium.

Communication chip 1707 may implement any wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1707 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1707 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1707 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1707 may operate in accordance with other wireless protocols in other embodiments. Computing device 1700 may include an antenna 1713 to facilitate wireless communications and/or to receive other wireless communications (such as AM or FM radio transmissions).

In some embodiments, communication chip 1707 may manage wired communications, such as electrical, optical, or any other suitable communication protocols (e.g., the Ethernet). As noted above, communication chip 1707 may include multiple communication chips. For instance, a first communication chip 1707 may be dedicated to shorter-range wireless communications such as Wi-Fi or Bluetooth, and a second communication chip 1707 may be dedicated to longer-range wireless communications such as GPS, EDGE, GPRS, CDMA, WiMAX, LTE, EV-DO, or others. In some embodiments, a first communication chip 1707 may be dedicated to wireless communications, and a second communication chip 1707 may be dedicated to wired communications.

Computing device 1700 may include battery/power circuitry 1708. Battery/power circuitry 1708 may include one or more energy storage devices (e.g., batteries or capacitors) and/or circuitry for coupling components of computing device 1700 to an energy source separate from computing device 1700 (e.g., AC line power).

Computing device 1700 may include a display device 1703 (or corresponding interface circuitry, as discussed above). Display device 1703 may include any visual indicators, such as a heads-up display, a computer monitor, a projector, a touchscreen display, a liquid crystal display (LCD), a light-emitting diode display, or a flat panel display, for example.

Computing device 1700 may include an audio output device 1704 (or corresponding interface circuitry, as discussed above). Audio output device 1704 may include any device that generates an audible indicator, such as speakers, headsets, or earbuds, for example.

Computing device 1700 may include an audio input device 1710 (or corresponding interface circuitry, as discussed above). Audio input device 1710 may include any device that generates a signal representative of a sound, such as microphones, microphone arrays, or digital instruments (e.g., instruments having a musical instrument digital interface (MIDI) output).

Computing device 1700 may include a global positioning system (GPS) device 1709 (or corresponding interface circuitry, as discussed above). GPS device 1709 may be in communication with a satellite-based system and may receive a location of computing device 1700, as known in the art.

Computing device 1700 may include another output device 1705 (or corresponding interface circuitry, as discussed above). Examples include an audio codec, a video codec, a printer, a wired or wireless transmitter for providing information to other devices, or an additional storage device.

Computing device 1700 may include another input device 1711 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1700 may include a security interface device 1712. Security interface device 1712 may include any device that provides security measures for computing device 1700 such as intrusion detection, biometric validation, security encode or decode, managing access lists, malware detection, or spyware detection.

Computing device 1700, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example the above embodiments may include specific combinations of features as further provided below.

In first examples, an integrated circuit (IC) assembly comprises a plurality of IC die structures, a base comprising a routing metallization structure coupled to the IC die structures. A perimeter edge of the base extends no more than 700 μm beyond a nearest edge sidewall of the IC die structures. The IC assembly comprises a first organic dielectric material between a first side of at least one of the IC die structures and an opposing first side of the base, and one or more second organic dielectric materials, adjacent to a sidewall of the IC die structures. The one or more second organic dielectric materials have one or more chemical compositions distinct from that of the first organic dielectric material. The one or more second organic dielectric materials separate the first organic dielectric material from the perimeter edge of the base along at least the nearest edge sidewall of the IC die structures.

In second examples, for any of the first examples the first side of the IC die structures comprises first electrical interconnect interface features. The first side of the routing metallization structure comprises second electrical interconnect interface features coupled to the first electrical interconnect interface features. A second side of the routing metallization structure comprises third electrical interconnect interface features. The assembly further comprises a package substrate structure. A first side of the package substrate structure comprises fourth electrical interconnect interface features coupled to the third electrical interconnect interface features on the second side of the base.

In third examples, for any of the second examples the assembly further comprises first interconnect features between the first electrical interconnect interface features and the second electrical interconnect interface feature. The first interconnect features comprise a solder alloy and extend through a thickness of the first organic dielectric material. The assembly comprises second interconnect features between the third electrical interconnect interface features and the fourth electrical interconnect interface features. The second interconnect features also comprise a solder alloy.

In fourth examples, for any of the second through third examples the first organic dielectric material has an outer sidewall comprising a first portion with a concave surface curvature and a second portion with a more vertical profile than the first portion.

In fifth examples, for any of the fourth examples the second portion of the outer sidewall of the first organic dielectric material is no more than 150 μm from the nearest edge sidewall of the first or second IC die structures.

In sixth examples, for any of the fifth examples the one or more second organic dielectric materials comprise a bead of second organic dielectric material in contact with a sidewall of the first organic dielectric material, and a capping layer of second organic dielectric material over, and in contact with, the bead of second organic dielectric material.

In seventh examples, for any of the sixth examples at least some portion of a transverse cross-sectional profile of the bead of second organic dielectric material has convex surface curvature.

In eighth examples, for any of the sixth examples the bead of the second organic dielectric material has a height exceeding a spacing between the first side of each of the first and second IC die structures and the first side of the routing metallization structure.

In ninth examples, for any of the eighth examples a thickness of the first organic dielectric material in contact with an inner edge of the bead of the second organic dielectric material is less than the height of the bead.

In tenth examples, for any of the sixth through ninth examples the bead and the capping layer of the second organic dielectric material have substantially the same chemical composition.

In eleventh examples, for any of the fourth through tenth examples the routing metallization structure comprises a metallization feature directly below the second portion, and wherein the one or more second organic dielectric materials are in direct contact with the metallization feature.

In twelfth examples, for any of the eleventh examples the metallization feature is within a metallization level below that of the second interconnect interface features and wherein the one or more second organic dielectric materials are within a recess within the first side of the routing metallization structure.

In thirteenth examples, for any of the first through twelfth examples the one or more second organic dielectric materials comprise a polysiloxane, a polyurethane, a polyacrylate, or an epoxy.

In fourteenth examples, an integrated circuit (IC) assembly comprises a multi-chip module comprising a first IC die structure adjacent to a second IC die structure, and a module base comprising a routing metallization structure coupled through solder features to first and second IC die structures. An outer perimeter edge of the module base extends beyond an outer perimeter edge of each of the first IC structure and the second IC structure. The multi-chip module comprises an underfill material around the solder features and between at least one of the first and second IC structures and the module base. The underfill material has an outer perimeter sidewall comprising a first portion with a concave surface curvature and a second portion with a more vertical profile than the first portion. The multi-chip module comprises one or more mold materials, surrounding the first and second IC structures, surrounding the outer perimeter sidewall of the underfill material, and extending to the outer perimeter edge of the module base. The assembly comprises a package substrate structure electrically coupled to the multi-chip module through interconnect structures between interface features of the routing metallization structure and interface features of the package substrate structure.

In fifteenth examples, for any of the fourteenth examples the second portion of the outer sidewall of the underfill material is no more than 150 μm from the nearest edge sidewall of the first or second IC die structures. The outer perimeter edge of the routing metallization structure extends no more than 700 μm beyond a nearest outer perimeter edge of the first IC die structure or the second IC die structure.

In sixteenth examples, for any of the fifteenth examples the one or more mold materials comprise a layer of mold material in contact with the first portion of the outer perimeter sidewall of the underfill material.

In seventeenth examples, a method of manufacturing an integrated circuit (IC) assembly comprises attaching a first side of each of a plurality of IC die structures to a first side of a routing structure, dispensing an underfill material between the first side of at least one of the first and second IC die structure and the first side of the routing structure, confining the underfill material with a barrier material having a different chemical composition than the underfill material, or through patterning an outer perimeter edge of the underfill material, and overmolding the first and second IC die structures and the routing structure, the overmolding encapsulating the outer perimeter edge of the underfill material.

In eighteenth examples, for any of the seventeenth examples the method comprises curing the underfill material, the dispensing and the curing forming a fillet of the underfill material extending a first distance beyond a perimeter edge of the IC die structures. Confining the underfill material further comprises impeding a flow of the underfill material with the barrier material, or truncating the fillet of the underfill material.

In nineteenth examples, for any of the eighteenth examples confining the underfill material further comprises truncating the fillet of the underfill material through laser ablation of the underfill material.

In twentieth examples, for any of the eighteenth examples confining the underfill material further comprises depositing a bead of the barrier material prior to dispensing or curing the underfill material.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An integrated circuit (IC) assembly, comprising:
a plurality of IC die structures;
a base comprising a routing metallization structure coupled to the IC die structures, wherein a perimeter edge of the base extends no more than 700 μm beyond a nearest edge sidewall of the IC die structures;
a first organic dielectric material between a first side of at least one of the IC die structures and an opposing first side of the base; and
one or more second organic dielectric materials, adjacent to a sidewall of the IC die structures, wherein:
the one or more second organic dielectric materials have one or more chemical compositions distinct from that of the first organic dielectric material; and
the one or more second organic dielectric materials separate the first organic dielectric material from the perimeter edge of the base along at least the nearest edge sidewall of the IC die structures.

2. The IC assembly of claim 1, wherein:
the first side of the IC die structures comprises first electrical interconnect interface features;
the first side of the routing metallization structure comprises second electrical interconnect interface features coupled to the first electrical interconnect interface features;
a second side of the routing metallization structure comprises third electrical interconnect interface features; and
further comprising a package substrate structure, wherein a first side of the package substrate structure comprises fourth electrical interconnect interface features coupled to the third electrical interconnect interface features on the second side of the base.

3. The IC assembly of claim 2, further comprising:
first interconnect features between the first electrical interconnect interface features and the second electrical interconnect interface features, wherein the first interconnect features comprise a solder alloy and extend through a thickness of the first organic dielectric material; and
second interconnect features between the third electrical interconnect interface features and the fourth electrical interconnect interface features, wherein the second interconnect features also comprise a solder alloy.

4. The IC assembly of claim 2, wherein the first organic dielectric material has an outer sidewall comprising a first portion with a concave surface curvature and a second portion with a more vertical profile than the first portion.

5. The IC assembly of claim 4, wherein the second portion of the outer sidewall of the first organic dielectric material is no more than 150 μm from the nearest edge sidewall of the first or second IC die structures.

6. The IC assembly of claim 5, wherein:
the one or more second organic dielectric materials comprise:
a bead of second organic dielectric material in contact with a sidewall of the first organic dielectric material; and
a capping layer of second organic dielectric material over, and in contact with, the bead of second organic dielectric material.

7. The IC assembly of claim 6, wherein at least some portion of a transverse cross-sectional profile of the bead of second organic dielectric material has convex surface curvature.

8. The IC assembly of claim 6, wherein the bead of the second organic dielectric material has a height exceeding a spacing between the first side of each of the first and second IC die structures and the first side of the routing metallization structure.

9. The IC assembly of claim 8, wherein a thickness of the first organic dielectric material in contact with an inner edge of the bead of the second organic dielectric material is less than the height of the bead.

10. The IC assembly of claim 6, wherein the bead and the capping layer of the second organic dielectric material have substantially the same chemical composition.

11. The IC assembly of claim 4, wherein the routing metallization structure comprises a metallization feature directly below the second portion, and wherein the one or more second organic dielectric materials are in direct contact with the metallization feature.

12. The IC assembly of claim 11, wherein the metallization feature is within a metallization level below that of the second interconnect interface features and wherein the one or more second organic dielectric materials are within a recess within the first side of the routing metallization structure.

13. The IC assembly of claim 1, wherein the one or more second organic dielectric materials comprise a polysiloxane, a polyurethane, a polyacrylate, or an epoxy.

14. An integrated circuit (IC) assembly, comprising:
a multi-chip module comprising:
a first IC die structure adjacent to a second IC die structure;
a module base comprising a routing metallization structure coupled through solder features to first and second IC die structures, wherein an outer perimeter edge of the module base extends beyond an outer perimeter edge of each of the first IC structure and the second IC structure;
an underfill material around the solder features and between at least one of the first and second IC structures and the module base, wherein the underfill material has an outer perimeter sidewall comprising a first portion with a concave surface curvature and a second portion with a more vertical profile than the first portion; and
one or more mold materials, surrounding the first and second IC structures, surrounding the outer perimeter sidewall of the underfill material, and extending to the outer perimeter edge of the module base; and
a package substrate structure electrically coupled to the multi-chip module through interconnect structures between interface features of the routing metallization structure and interface features of the package substrate structure.

15. The IC assembly of claim 14, wherein:
the second portion of the outer sidewall of the underfill material is no more than 150 μm from the nearest edge sidewall of the first or second IC die structures; and
the outer perimeter edge of the routing metallization structure extends no more than 700 μm beyond a nearest outer perimeter edge of the first IC die structure or the second IC die structure.

16. The IC assembly of claim 15, wherein the one or more mold materials comprise a layer of mold material in contact with the first portion of the outer perimeter sidewall of the underfill material.

17. A method of manufacturing an integrated circuit (IC) assembly, the method comprising:
attaching a first side of each of a plurality of IC die structures to a first side of a routing structure;
dispensing an underfill material between the first side of at least one of the first and second IC die structure and the first side of the routing structure;
confining the underfill material with a barrier material having a different chemical composition than the underfill material, or through patterning an outer perimeter edge of the underfill material; and
overmolding the first and second IC die structures and the routing structure, the overmolding encapsulating the outer perimeter edge of the underfill material.

18. The method of claim 17, further comprising:
curing the underfill material, the dispensing and the curing forming a fillet of the underfill material extending a first distance beyond a perimeter edge of the IC die structures; and
wherein confining the underfill material further comprises:
impeding a flow of the underfill material with the barrier material; or
truncating the fillet of the underfill material.

19. The method of claim 18, wherein confining the underfill material further comprises truncating the fillet of the underfill material through laser ablation of the underfill material.

20. The method of claim 18, wherein confining the underfill material further comprises depositing a bead of the barrier material prior to dispensing or curing the underfill material.
